(19) United States
(12) Patent Application Publication
(10) Pub. No.: US 2009/0246911 A1
(43) Pub. Date: Oct. 1, 2009

(54) SUBSTRATE FOR MOUNTING ELECTRONIC COMPONENTS AND ITS METHOD OF MANUFACTURE

(75) Inventor: Hiroyuki Watanabe, Ogaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: IBIDEN, CO., LTD., Ogaki-shi (JP)

(21) Appl. No.: 12/325,897

(22) Filed: Dec. 1, 2008

Related U.S. Application Data
(60) Provisional application No. 61/040,072, filed on Mar. 27, 2008.

(51) Int. Cl. H01L 21/50; H05K 1/09; H05K 3/10

(52) U.S. Cl. 438/108; 174/257; 29/846; 257/E21.499

(57) ABSTRACT

A substrate for mounting electronic components includes an insulating layer and a pad formed on a surface of the insulating layer, the pad configured to mount an electronic component to the substrate. A solder bump is formed on the pad and configured to connecting the pad to a bump of an electronic component, the solder bump including a metal as a major component of the solder bump. A metal film is formed on a surface of the solder bump, the metal film comprising a different metal from the major component of said solder

### CROSS-REFERENCE TO RELATED APPLICATIONS

The present application claims the benefits of priority to U.S. Application No. 61/040,072, filed Mar. 27, 2008. The contents of that application are incorporated herein by reference in their entirety.

### BACKGROUND OF THE INVENTION

1. Technical Field

The present invention relates to a substrate for mounting electronic components and its method of manufacture, relating specifically to a substrate for mounting electronic components that performs flip chip implementation using an Au bump and a solder bump as well as its method of manufacture.

2. Discussion of the Background

Along with improved functionalization of electronic devices, there has been a need for a highly integrated and narrow-pitched semiconductor chip to be mounted on a substrate for mounting electronic components. Technology for implementing a narrow-pitched semiconductor chip includes flip chip implementation, in which a bear chip is connected to a package substrate. In the flip chip implementation, a bump electrode formed on the semiconductor chip is connected opposite from the land on the substrate. As disclosed in the Japanese Unexamined Patent Application Publication 2006-165303, one of these flip chip implementations employs a method of flip interconnection between an Au bump of the bear chip and a copper pad of the substrate. The contents of this publication are incorporated herein by reference in their entirety.

### BRIEF SUMMARY OF EMBODIMENTS OF THE INVENTION

One aspect of the invention includes a substrate for mounting electronic components. The substrate includes an insulating layer and a pad formed on a surface of the insulating layer, the pad configured to mount an electronic component to the substrate. A solder bump is formed on the pad and configured to connect the pad to a bump of an electronic component, the solder bump including a metal as a major component of the solder bump. A metal film is formed on the surface of the solder bump, the metal film comprising a different metal from the major component of the solder bump.

### BRIEF DESCRIPTION OF THE DRAWINGS

FIG. 1(A) shows the composition of a substrate for mounting electronic components according to the first embodiment of the present invention, while FIG. 1(B) is an illustration showing a state in which a semiconductor chip is processed through flip chip implementation on said substrate for mounting electronic components.

FIGS. 2(A), 2(B), and 2(C) provide a flowchart showing a manufacturing process of the substrate for mounting electronic components of the first embodiment.

FIG. 3(A) is an illustration showing the composition of the semiconductor chip according to the second embodiment of the present invention, while FIG. 3(B) is an illustration showing a state in which said semiconductor chip is processed through flip chip implementation on the substrate for mounting electronic components.

FIGS. 4(A), 4(B), and 4(C) provide a flowchart showing a manufacturing process of the semiconductor chip of the second embodiment.

FIGS. 5(A) and 5(B) provide an illustration showing an example of the substrate for mounting electronic components according to the embodiments of the present invention.

FIGS. 6(A) and 6(B) provide an illustration showing an example of the substrate for mounting electronic components according to the embodiments of the present invention.

FIG. 7(A) is an illustration showing the composition of the substrate for mounting electronic components according to the conventional technology, while FIG. 7(B) is an enlarged pattern diagram of the joint where the semiconductor chip is processed through flip chip interconnection on said substrate for mounting electronic components.

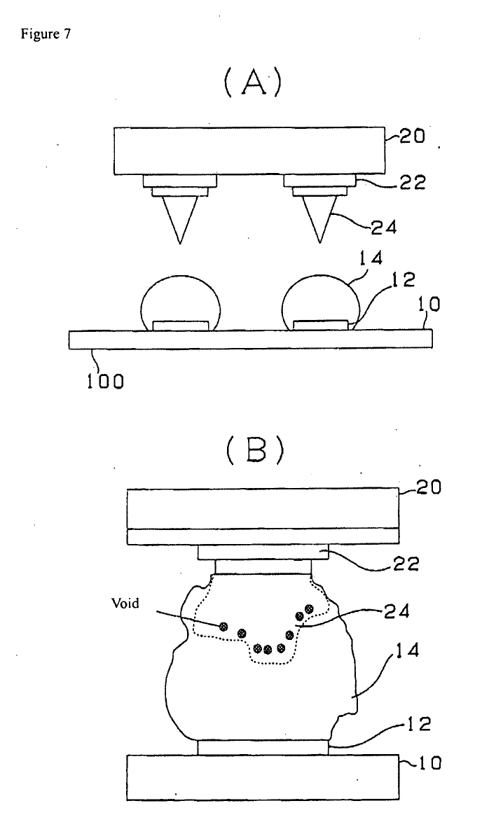

### DETAILED DESCRIPTION OF THE PREFERRED EMBODIMENTS

As noted above electronic components having an Au bump may be connected with a substrate for mounting electronic components having a solder bump through flip chip interconnection. An object of the present invention is to provide a substrate for mounting electronic components on which electronic components having an Au bump can be implemented with high reliability, as well as its method of manufacture.

In order to achieve the above-mentioned objective, an embodiment of the invention is a substrate for mounting electronic components of the present invention including an insulating layer. A pad is formed on the surface of said insulating layer to mount electronic components having an Au bump, and a solder bump is formed on the pad to connect the pad and the Au bump. A metal film is formed on the surface of the solder bump, the metal film is composed of a different metal from the main component of the solder bump.

In order to achieve the above-mentioned objective, an embodiment of the invention is a method for manufacturing a substrate for mounting electronic components. The method includes forming a pad on the surface of an insulating layer to mount electronic components having an Au bump, forming a solder bump on the pad to connect with the Au bump, and forming a metal film composed of a different metal from the main component of the solder bump.

In order to achieve the above-mentioned objective, another embodiment includes a method for manufacturing an electronic device. The method includes forming a pad on the surface of an insulating layer to mount electronic components having an Au bump and forming a solder bump on the pad to connect with the Au bump. Also included is forming a metal film composed of a different metal from the main component of the solder bump on the surface of the Au bump, and implementing flip chip interconnection between the Au bump and the solder bump to mount electronic components on the pad.

For the substrate for mounting electronic components of the present invention, a metal film is formed on the surface of the solder bump. The metal film is composed of a metal other than the main component of the solder bump. Thus, the connection reliability between the Au bump and the solder bump is improved. Therefore, the present invention allows for a substrate for mounting electronic components that enables the mounting of electronic components having an Au bump to be provided with high reliability.

The embodiments will now be described with reference to the accompanying drawings.

### First Embodiment

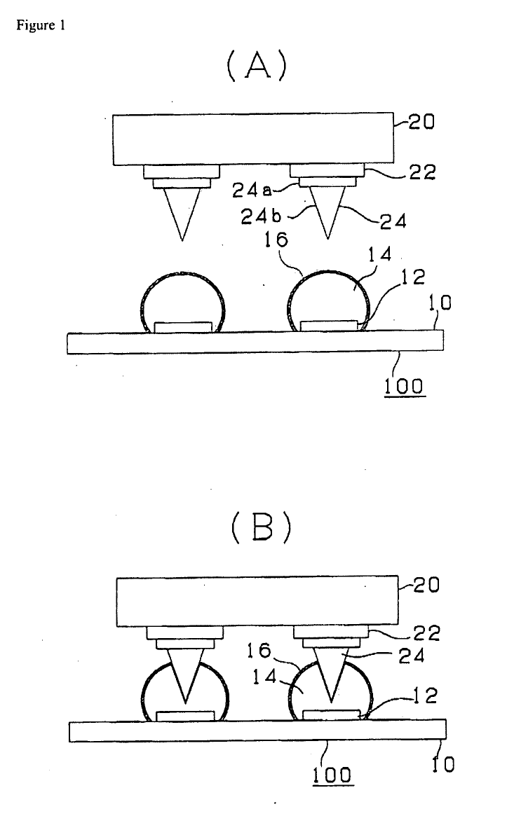

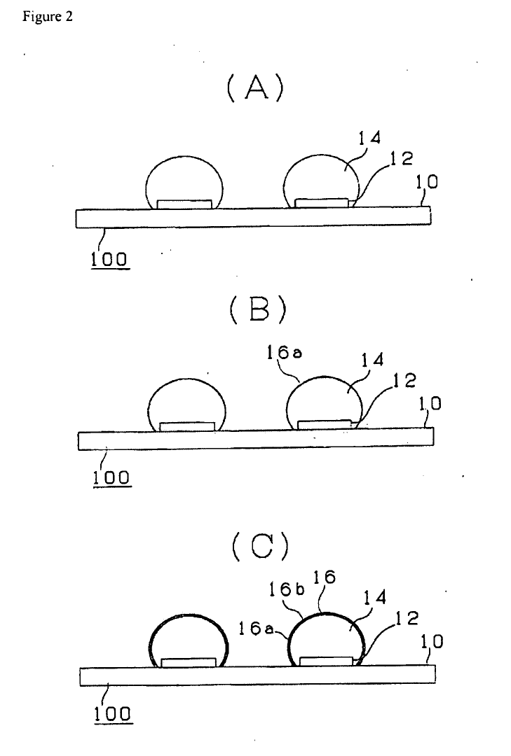

With reference to FIG. 1 and FIG. 2, a substrate for flip chip interconnection according to the first embodiment of the present invention will be described. As shown in FIG. 1(A), the substrate for mounting electronic components 100 of the first embodiment comprises: an insulating layer 10; a pad 12 formed on the insulating layer 10; a solder bump 14 formed on the pad; and a metal film 16 formed on the surface of the solder bump 14. Furthermore, as shown in FIG. 1(B), the solder bump 14 connects (through flip chip interconnection) an Au bump 24 of electronic components 20 with the pad 12 for mounting electronic components. As shown in FIG. 1(B), the Au bump 24 is preferably an Au bump composed of a cylindrical base 24a and a conical stud part 24b.

The metal film 16 is composed of a metal other than the main component of the solder bump. Thus, it makes the formation of an alloy layer composed of the Au bump and the main component of the solder bump difficult. Therefore, it prevents the occurrence of voids within the bump. As a result, it inhibits the occurrence of cracks that decrease the connection reliability between the electronic components and the substrate for mounting electronic components. When an IC chip generates heat, it is possible to prevent increases in resistance caused by the expansion of cracks within the bump. It is possible to prevent occurrences of crack within the bump caused by thermal expansion of voids. Therefore, the substrate for mounting electronic components 100 of the first embodiment is preferred as a substrate for mounting electronic components having an Au bump.

Herein, the main component metal of the solder bump refers to the metal having the highest wt % among the several metals that compose the solder bump.

The solder bump is an Sn-series solder bump, and the metal film is preferably composed of a metal other than Sn. Here, the Sn-series solder bump refers to a solder bump comprising Sn as its main component. Because the Sn-series solder bump has a low melting point, during the flip chip interconnection implemented by reflow, it prevents the formation of an alloy layer. Concrete examples of an Sn-series solder bump include Sn/Pb, Sn/Ag, Sn/Cu, Sn/Ag/Cu, and Sn.

The growth rate of an alloy formed by the metal composing a metal film and the main component metal of the solder bump is preferably slower than that of an alloy formed by Au and the main component metal of the solder bump.

The growth rate of an alloy formed by the metal composing a metal film and gold is preferably slower than that of an alloy formed by Au and the main component metal of said solder bump.

The growth rate of an alloy formed by the metal composing a metal film and the main component metal of the solder bump and the growth rate of an alloy formed by the metal composing a metal film and gold are preferably slower than that of an alloy formed by Au and the main component metal of said solder bump. When the relationships between the alloy growth rates are as described above, the diffusion rate of gold within the solder bump and the metal film is decreased, or the diffusion rate of the metal comprising the solder bump (particularly the main component metal) within the Au bump and the metal film is decreased, or the diffusion rate of the metal of the metal film within the solder bump and the Au bump is decreased. Therefore, it prevents the occurrence of voids within the bump and the metal film.

The solder bump is preferably an Sn-series solder bump, and the metal film is preferably composed of one metal chosen from copper, silver, Pd, platinum, lead, nickel, cadmium, or zinc. It is possible to prevent gold within the Au bump from diffusing into the metal film or the solder bump. It is also possible to prevent the metal within the solder bump (particularly the main component metal) from diffusing into the metal film or the Au bump. As a result, it prevents the occurrence of voids within the bump or the metal film.

The metal film is preferably composed of one metal chosen from the precious metals. It inhibits the formation of an alloy layer composed of gold and the main component of the solder bump. It prevents gold within the Au bump from diffusing into the metal film and the solder bump. It also prevents the metal within the solder bump (particularly the main component metal) from diffusing into the Au bump. As a result, it prevents the occurrence of voids within the bump and the metal film.

As a combination of the metal film and the solder bump, it is preferred that the metal film be Pd and that the solder bump be Sn. With this combination, an alloy metal layer cannot be formed easily, resulting in high connection reliability between the Au bump and the solder bump.

FIG. 1(B) shows a state in which flip chip implementation is performed for the semiconductor chip 20 to the substrate for mounting electronic components 100. During the flip chip interconnection, in order for the abovementioned solder bump to melt, the semiconductor chip 20 is connected with the substrate for mounting electronic components at a temperature 20-30° C. higher than the melting temperature of tin or tin alloy (for example, 230° C. for tin). Electronic components are connected with the substrate for mounting electronic components via the Au bump and the solder bump.

Herein, for the printed-wiring board 10 of the first embodiment, the surface of the solder bump 14 composed of tin is coated with a palladium film 16. Compared to gold, palladium does not easily form an alloy layer with Sn. Therefore, during reflow interconnection or heat generation by IC chips, palladium inhibits the formation of an alloy of the gold of the Au bump and the tin of the solder bump 14. As a result, it prevents the occurrence of voids within the Au bump and the solder bump. It also prevents the occurrence of cracks within the bump caused by voids. It prevents increases in resistance caused by the expansion of cracks with the bump when the semiconductor chip 20 generates heat. It prevents damage in the joint (between the solder bump and the Au bump) caused by thermal expansion of voids within the bump. Therefore, it improves the connection reliability between the Au bump and the solder bump.

For the first embodiment, the solder bump 14 is covered with the palladium film 16. However, other than palladium, it is possible to use a metal having a slower diffusion rate than the gold composing the Au bump. For example, silver, indium, platinum, and others are preferred for the metal film. Because the diffusion rate to Sn has a substantially similar tendency as the rate during ionization, it is possible to employ a metal in which the ionization tendency is smaller than that of tin and larger than that of gold. Theoretically, metals such as antimony (Sb), bismuth (Bi), copper (Cu), and others are also employable. However, because these metals cause an oxide layer to form on the surface, precious metals are preferred. Herein, silver can be coated on the surface of the solder bump through plating. Platinum can be coated on the solder bump through sputtering after creating a mask along with the solder bump of the printed-wiring board.

Continuously referring to FIG. 2, the method for manufacturing the substrate for mounting electronic components 100 according to the first embodiment will be described. Firstly, a pad 12 is formed on an insulating layer 10. Secondly, a tin solder is mounted on the pad 12 to perform reflow, thereby forming a solder bump 14 on the pad 12 as shown in FIG. 2(A). Then, palladium is precipitated on the solder bump through displacement plating. That is, a printed-wiring board 10 on which a tin bump is formed is immersed into a palladium (Pd) solution, causing the following chemical reaction in which Sn, which is prone to ionization, dissolves into the solution, and thus Pd, which has a lower ionization tendency than Sn, is precipitated on the solder surface.

Sn+Pd(2+)→Sn(2+)+Pd [Formula 1]

This displacement plating forms a displacement plating film 16a composed of palladium on the surface of the solder bump 14 by immersing the substrate for mounting electronic components 100 shown in FIG. 2(A) into a pretreated chemical (KAT-450 produced by Uemura & Co., Ltd.) and displacing Sn and Pd under the following conditions (FIG. 2(B)).

[Displacement plating solution]

| | |
|---|---|
| Pd concentration | 8-16 mg/L |
| Sulfuric acid (62.5%) | 17-36 g/L |
| Temperature | 20-30° C. |
| Immersion period | 1.5 minutes |

For the displacement plating, the thickness of the precipitated Pd is insufficient to act as a barrier metal layer in order to prevent the gold from diffusing. To achieve a thickness that allows it to act as a barrier metal layer (for example, 0.03-0.07 μm), electroless Pd plating is performed. Electroless Pd plating refers to a method for precipitating Pd on the surface using Pd precipitated on the surface of the solder bump (a displacement plating film composed of palladium) as the core (catalyst). By employing electroless Pd plating, an electroless plating film (electroless Pd plating film) with a specified thickness is formed on the surface of the solder bump. As such, by performing displacement plating and electroless plating, a metal film is formed on the surface of the solder bump. The metal film is composed of the displacement plating film and the electroless plating film thereon.

This electroless Pd plating completes the metal film 16 by immersing the substrate for mounting electronic components 100 shown in FIG. 2(B) into electroless Pd plating produced by Electroplating Engineers of Japan, Ltd. (EEJA) to form the palladium plating film 16b on the solder bump 14 with a specified thickness under the following conditions (FIG. 2(C)).

[Displacement plating solution]

| | |
|---|---|
| Pd concentration | 0.4-0.8 g/L |
| Precipitation rate | 0.5-0.9 μm/hr |
| Immersion period | 4.0 minutes |

For the method of manufacturing the printed-wiring board according to the first embodiment, a palladium displacement plating film 16a is formed on the surface of the solder bump 14 through displacement plating and a palladium electroless plating film 16b with a specified thickness is formed on said palladium displacement plating film through electroless plating. This allows the surface of the solder bump 14 composed of tin to be coated with palladium. Therefore, during reflow interconnection and heat generation by a semiconductor, it can prevent gold from diffusing into tin by employing palladium having a slower diffusion rate than gold. As a result, it can prevent the occurrence of voids within the Au bump and the solder bump.

### Second Embodiment

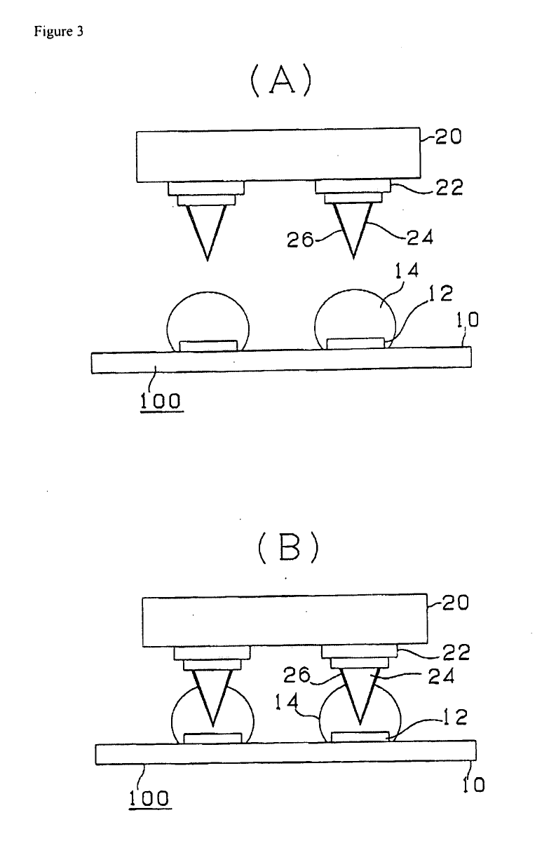

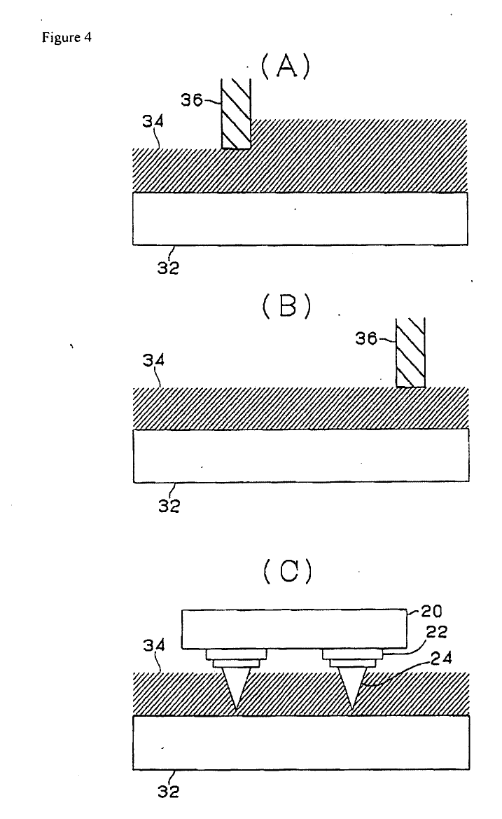

Referring to FIG. 3 and FIG. 4, a flip chip interconnection semiconductor device according to the second embodiment of the present invention will be described. FIG. 3(A) shows the substrate for mounting electronic components 100 according to the second embodiment and the semiconductor chip (electronic device) 20 connected to said substrate for mounting electronic components 100 through flip chip interconnection. The substrate for mounting electronic components 100 is equipped with the copper land 12. On said land 12, a solder bump 14 composed of Sn (60 wt %) and Pb (40 wt %) is formed. On the other hand, for the semiconductor chip 20, an aluminum pad 22 is formed. On said pad 22, an Au bump 24 is created, and on said Au bump 24, a platinum film 26 is formed.

FIG. 3(B) shows a state in which flip chip interconnection is implemented for the semiconductor chip 20 to the substrate for mounting electronic components 100.

Herein, for the semiconductor chip 20 of the second embodiment, a platinum film (metal film) is formed on the surface of the Au bump to prevent the occurrence of voids within the Au bump, the solder bump, and the metal film. This improves the connection reliability between the electronic components connected with the Au bump via the solder bump and the device for mounting electronic components.

For the second embodiment, the Au bump 24 is coated with the platinum film 26. For the metal film, it is possible to use, besides platinum, one composed of a metal that is less likely to form an alloy with Sn than the gold comprising the Au bump. For example, silver, indium, palladium, or others can be employed.

Continuously referring to FIG. 4, the method for manufacturing the semiconductor chip 20 according to the second embodiment will be described.

As shown in FIG. 4(A), a flux 34 on which platinum is diffused is mounted on a flat table 32. A squeegee 36 is used to spread the flux 34, thereby adjusting the thickness of the flux on which platinum is diffused to 10 μm as shown in FIG. 4(B). Thereafter, as shown in FIG. 4(C), the Au bump 24 of the semiconductor chip 20 is inserted into the flux 34 to coat the surface of the Au bump 24 with the platinum film 26.

For the method of manufacturing the semiconductor chip according to the second embodiment, the surface of the Au bump 24 is coated with the platinum film 26 by being immersed in flux on which platinum is diffused. This allows the surface of the Au bump 24 to be coated with platinum and for the occurrence of voids within the bump to be prevented during reflow and heat generation by the semiconductor.

### INDUSTRIAL APPLICABILITY

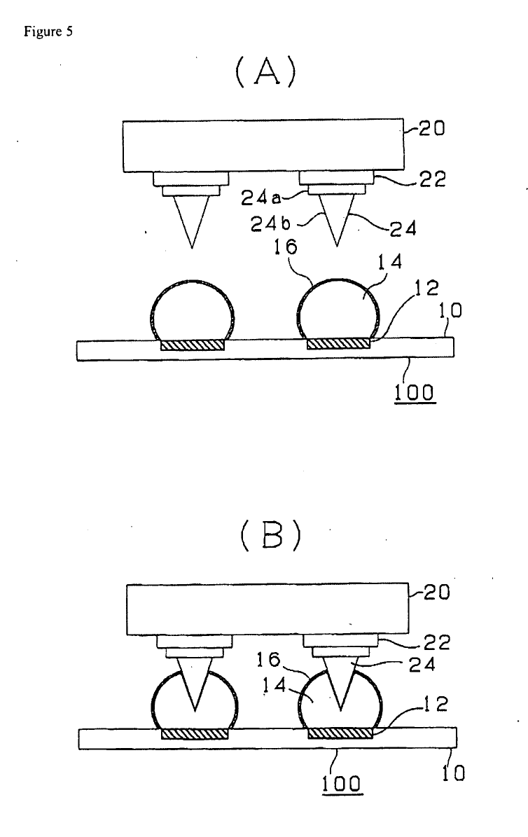

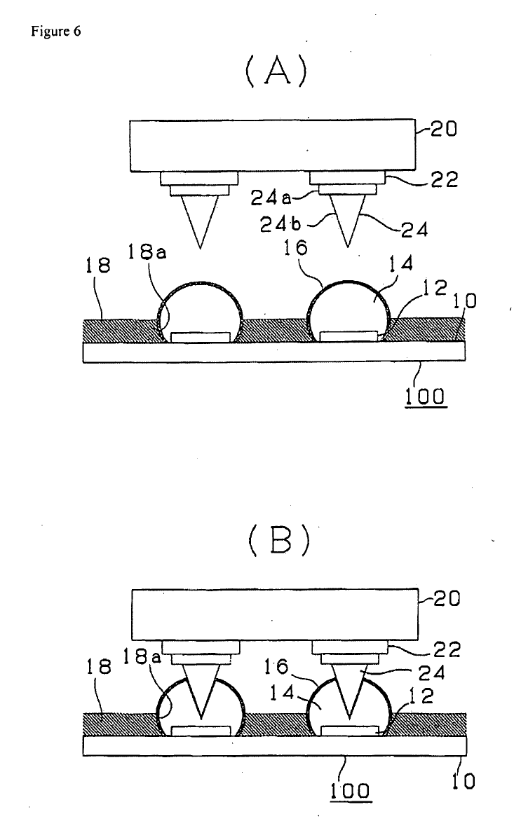

For the abovementioned embodiments, an example is cited in which flip chip implementation is performed for the semiconductor chip on the printed-wiring board. However, the composition of the present invention can be used for any flip chip implementation as long as it employs an Au bump and a tin solder bump. As the substrate for mounting electronic components 100, a substrate shown in FIG. 5 and FIG. 6 can be used. For the substrate shown in FIG. 5, the pad 12 is embedded within the insulating layer 10. Then, the surface of the pad and that of the insulating layer are located at a substantially similar level. For the substrate shown in FIG. 6, a solder resist layer 18 that has an opening 18a to expose the pad is formed.

In an embodiment of the invention, a gold stud bump is used to provide a substrate for flip chip interconnection in which Kirkendall voids do not occur during reflow interconnection with a solder bump. For a printed-wiring board 10, the surface of a solder bump 14 composed of tin is coated with a palladium film having a slower diffusion rate than the gold composing a gold stud bump 24. Therefore, during the reflow interconnection, the palladium acts to decrease the diffusion rate of the gold of the gold stud bump within the tin of the solder bump, thereby preventing the occurrence of Kirkendall voids. This allows for a reduction in the development of internal cracks caused by Kirkendall voids and prevents increases in resistance caused by expanded internal cracks when a semiconductor chip 20 generates heat, and it also prevents decreases in connection reliability caused by thermal expansion of air within the inner cracks.

Obviously, numerous modifications and variations of the present invention are possible in light of the above teachings. It is therefore to be understood that within the scope of the appended claims, the invention may be practiced otherwise than as specifically described herein.

1. A substrate for mounting electronic components, comprising:
an insulating layer;
a pad formed on a surface of said insulating layer, said pad configured to mount an electronic component to the substrate;
a solder bump formed on the pad and configured to connecting said pad to a bump of an electronic component, the solder bump comprising a metal as a major component of the solder bump; and
a metal film formed on a surface of said solder bump, wherein said metal film comprising a different metal from the major component of said solder bump.

2. The substrate for mounting electronic components according to claim 1, wherein said solder bump is an Sn-series solder bump and the metal film comprising a different metal from the major component Sn of said solder bump.

3. The substrate for mounting electronic components according to claim 1, wherein the metal film comprising a metal such that a growth rate of an alloy formed by the metal of said metal film and the major component metal of said solder bump is slower than a growth rate of an alloy formed by Au and the major component metal of said solder bump.

4. The substrate for mounting electronic components according to claim 1, wherein the metal film comprising a metal such that a growth rate of an alloy formed by a metal of said metal film and Au is slower than a growth rate of an alloy formed by Au and the major component metal of said solder bump.

5. The substrate for mounting electronic components according to claim 2, wherein said metal film comprising one metal chosen from copper, silver, Pd, platinum, lead, nickel, cadmium, or zinc.

6. The substrate for mounting electronic components according to claim 2, wherein said metal film comprising one metal chosen from precious metals.

7. The substrate for mounting electronic components according to claim 1, further comprising a solder resist layer having an opening to expose said pad, formed on said substrate for mounting electronic components.

8. The substrate for mounting electronic components according to claim 1, wherein said metal film comprising Pd.

9. The substrate for mounting electronic components according to claim 7, wherein said solder bump comprising Sn.

10. The substrate for mounting electronic components according to claim 1, wherein the surface of said pad protrudes from the surface of said insulating layer.

11. The substrate for mounting electronic components according to claim 1, wherein the surface of said pad and that of said insulating layer are situated substantially at the same level.

12. The substrate of claim 1, wherein said metal film comprises a metal film covering an entire surface of the solder bump.

13. The substrate for mounting electronic components according to claim 2, wherein said metal film consists of one metal chosen from the precious metals.

14. The substrate for mounting electronic components according to claim 1, wherein said metal film consisting of Pd.

15. A method for manufacturing a substrate for mounting electronic components, comprising:
forming a pad on an insulating layer of the substrate, the pad configured to mount electronic components to the substrate;
forming a solder bump on said pad, the solder bump configured to connect said pad to a bump of an electronic component, the solder bump comprising a metal as a major component of the solder bump; and
forming a metal film on a surface of said solder bump, the metal film comprising a different metal from the major component of said solder bump.

16. The method for manufacturing a substrate for mounting electronic components according to claim 15, wherein said metal film is formed through displacement plating.

17. The method for manufacturing a substrate for mounting electronic components according to claim 15, wherein said metal film is formed through displacement plating and electroless plating.

18. The method for manufacturing a substrate for mounting electronic components according to claim 17, wherein the displacement plating and the electroless plating are used to form Pd.

19. A method for manufacturing an electronic device, comprising:
forming a pad on the surface of an insulating layer to mount electronic components;
forming a solder bump on said pad, the solder bump configured to connect with a bump, the solder bump comprising a metal as a major component of the solder bump;
forming a metal film on a surface of said solder bump, the metal film comprising a different metal from the major component of said solder bump; and
mounting electronic components on said substrate through flip chip interconnection of said Au bump and said solder bump.
